(19) United States
(12) Patent Application Publication
(10) Pub. No.: US 2021/0375926 A1
(43) Pub. Date: Dec. 2, 2021

(54) THREE-DIMENSIONAL NANORIBBON-BASED TWO-TRANSISTOR MEMORY CELLS

(71) Applicant: Intel Corporation, Santa Clara, CA (US)

(72) Inventors: Rishabh Mehandru, Portland, OR (US); Wilfred Gomes, Portland, OR (US); Kinyip Phoa, Beaverton, OR (US); Tahir Ghani, Portland, OR (US)

(73) Assignee: Intel Corporation, Santa Clara, CA (US)

(21) Appl. No.: 16/884,524

(22) Filed: May 27, 2020

(51) Int. Cl. H01L 27/11597; H01L 27/1159; H01L 29/06; H01L 29/423; H01L 29/78; H01L 29/786; H01L 21/02; H01L 29/66

(52) U.S. Cl. CPC H01L 27/11597; H01L 27/1159; H01L 29/0673; H01L 29/42392; H01L 29/66742; H01L 29/78618; H01L 29/78696; H01L 21/02603; H01L 29/6684; H01L 29/78391

(57) ABSTRACT

Described herein are IC devices that include semiconductor nanoribbons stacked over one another to realize high-density three-dimensional (3D) dynamic random-access memory (DRAM). An example device according to some embodiments of the present disclosure includes a first nanoribbon of a first semiconductor material, and a second nanoribbon of a second semiconductor material, where the second nanoribbon is stacked above the first, thus forming a 3D structure. The device further includes a first transistor having a first source or drain (S/D) region and a second S/D region in the first nanoribbon, and a second transistor having a first S/D region and a second S/D region in the second nanoribbon. The first transistor may be configured to store a memory state of the memory cell, and the second transistor may be configured to control access to the memory cell, thus, together forming a nanoribbon-based 2T memory cell.

### BACKGROUND

Embedded memory is important to the performance of modern system-on-a-chip (SoC) technology. Low-power and high-density embedded memory is used in many different computer products and further improvements are always desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a schematic illustration of an integrated circuit (IC) device with multiple layers of memory and logic that may include one or more three-dimensional (3D) nanoribbon-based two-transistor (2T) memory cells, according to some embodiments of the present disclosure.

FIG. 2 is a schematic illustration of an array of 2T memory cells, according to some embodiments of the present disclosure.

FIG. 3 is a perspective view of an IC structure with an example nanoribbon-based field-effect transistor (FET) that may be used as any of the transistors of a 2T memory cell, according to some embodiments of the present disclosure.

FIG. 4 is a perspective view of a first example of a 3D nanoribbon-based 2T memory cell, according to some embodiments of the present disclosure.

FIG. 5 is a perspective view of a second example of a 3D nanoribbon-based 2T memory cell, according to some embodiments of the present disclosure.

FIGS. 6A-6D are different perspective views of an example 3D memory array with a plurality of stacked 3D nanoribbon-based 2T memory cells of FIG. 4, according to some embodiments of the present disclosure.

FIG. 7 is a method for fabricating one or more 3D nanoribbon-based 2T memory cells, according to some embodiments of the present disclosure.

FIGS. 8A and 8B are top views of, respectively, a wafer and dies that may include one or more 3D nanoribbon-based 2T memory cells, according to some embodiments of the present disclosure.

FIG. 9 is a cross-sectional side view of an IC package that may include one or more 3D nanoribbon-based 2T memory cells, according to some embodiments of the present disclosure.

FIG. 10 is a cross-sectional side view of an IC device assembly that may include one or more 3D nanoribbon-based 2T memory cells, according to some embodiments of the present disclosure.

FIG. 11 is a block diagram of an example computing device that may include one or more 3D nanoribbon-based 2T memory cells in accordance with any of the embodiments disclosed herein.

### DETAILED DESCRIPTION

Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating 3D nanoribbon-based 2T memory cells and arrays of such memory cells, described herein, it might be useful to first understand phenomena that may come into play in context of memory devices. The following foundational information may be viewed as a basis from which the present disclosure may be properly explained. Such information is offered for purposes of explanation only and, accordingly, should not be construed in any way to limit the broad scope of the present disclosure and its potential applications.

Some memory devices may be considered “standalone” devices in that they are included in a chip that does not also include compute logic (where, as used herein, the term “compute logic devices” or simply “compute logic” or “logic devices,” refers to devices, e.g., transistors, for performing computing/processing operations). Other memory devices may be included in a chip along with compute logic and may be referred to as “embedded” memory devices. Using embedded memory to support compute logic may improve performance by bringing the memory and the compute logic closer together and eliminating interfaces that increase latency. Various embodiments of the present disclosure relate to embedded memory arrays, as well as corresponding methods and devices.

Some embodiments of the present disclosure may refer to dynamic random-access memory (DRAM) and in particular, embedded DRAM (eDRAM), because this type of memory has been introduced in the past to address the limitation in density and standby power of some other types of memory devices. However, embodiments of the present disclosure may be equally applicable to memory cells implemented other technologies. Thus, in general, memory cells described herein may be implemented as eDRAM cells, spin-transfer torque random access memory (STTRAM) cells, resistive random-access memory (RRAM) cells, or any other non-volatile memory cells.

A conventional memory cell, e.g., an eDRAM cell, may include a capacitor for storing a bit value, or a memory state (e.g., logical “1” or “0”) of the cell, and an access transistor controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”). The capacitor of a 1T-1C memory cell may be coupled to one source/drain (S/D) region/terminal of the access transistor (e.g., to the source region of the access transistor), while the other S/D region of the access transistor may be coupled to a bitline (BL), and a gate terminal of the transistor may be coupled to a wordline (WL). Since such a memory cell can be fabricated with as little as a single access transistor, it can provide higher density and lower standby power versus some other types of memory in the same process technology, e.g., static random-access memory (SRAM).

An alternative memory cell configuration would be to use a first transistor as a storage transistor, configured to store a bit value, or a memory state (e.g., logical “1” or “0”) of the cell, and to use a second transistor as an access transistor, configured to control access to the cell. Such a memory cell may be referred to as a “2T memory cell,” highlighting the fact that it uses two transistors—one for storage and one for controlling access.

Various memory cells have, conventionally, been implemented with access transistors being front end of line (FEOL), logic-process based, transistors implemented in an upper-most layer of a semiconductor substrate. Inventors of the present disclosure realized that using conventional FEOL transistors creates several challenges for increasing memory density, which challenges are especially pronounced for 2T memory cells.

One challenge resides in that, given a usable surface area of a substrate, there are only so many FEOL transistors that can be formed in that area, placing a significant limitation on the density of memory cells incorporating such transistors. In conventional solutions, attempts to increase memory density have included decreasing the critical dimensions of the memory cells, which requires ever-increasing process complexity and cost, resulting in diminishing returns and expected slow pace of memory scaling for future nodes.

Embodiments of the present disclosure may improve on at least some of the challenges and issues described above by increasing the number of active memory layers, to generate a vertically-stacked memory array design (e.g., DRAM design) using fewer masks and at a lower cost. In particular, embodiments of the present disclosure are based on using semiconductor nanoribbons stacked above one another to realize high-density 3D DRAM. In the context of the present disclosure, the term “above” may refer to being further away from the support structure or the FEOL of an IC device, while the term “below” refers to being closer towards the support structure or the FEOL of the IC device. Furthermore, as used herein, the term “nanoribbon” refers to an elongated semiconductor structure having a long axis parallel to a support structure (e.g., a substrate, a chip, or a wafer) over which a memory device is provided. In some settings, the term “nanoribbon” has been used to describe an elongated semiconductor structure that has a rectangular transverse cross-section (i.e., a cross-section in a plane perpendicular to the longitudinal axis of the structure), while the term “nanowire” has been used to describe a similar structure but with a circular transverse cross-section. In the present disclosure, the term “nanoribbon” is used to describe both such nanoribbons and such nanowires, as well as elongated semiconductor structures having transverse cross-sections of any geometry (e.g., oval, or a polygon with rounded corners). In some embodiments, such elongated semiconductor structures may have a longitudinal axis substantially parallel to the support structure. In other embodiments, such elongated semiconductor structures may have a longitudinal axis substantially perpendicular to the support structure.

Described herein are IC devices that include semiconductor nanoribbons stacked over one another to realize high-density 3D memory, e.g., 3D DRAM. An example device according to some embodiments of the present disclosure includes a first nanoribbon of a first semiconductor material, and a second nanoribbon of a second semiconductor material, where the second nanoribbon is stacked above the first, so that the first nanoribbon is between the second nanoribbon and a support structure such as a substrate, thus forming a 3D structure. The device further includes a first transistor having a first source or drain (S/D) region and a second S/D region in the first nanoribbon, and a second transistor having a first S/D region and a second S/D region in the second nanoribbon. The first transistor may be configured to store a memory state of the memory cell (therefore, such a transistor is a storage transistor), and the second transistor may be configured to control access to the memory cell (therefore, such a transistor is an access transistor), thus, together forming a nanoribbon-based 2T memory cell. When multiple such cells are implemented to realize a memory array, the nanoribbons may, advantageously, be arranged in such a way in 3D as to allow independent gate control of the access transistors of different cells. In various embodiments, the storage transistor may be configured to use various forms of state storage mechanisms, such as charge storage, magnetic field, resistance change, or material properties that can be electrically or magnetically controlled that can modulate the state storage mechanism.

Using nanoribbon-based transistors to implement 3D memory cells, e.g., 3D DRAM cells, with independent gate control may provide several advantages and enable unique architectures that were not possible with conventional, FEOL logic transistors. One advantage is that nanoribbon transistors may be moved to the back end of line (BEOL) layers of an advanced complementary metal oxide semiconductor (CMOS) process. Another advantage is that using a 2T memory cell architecture and incorporating access and storage transistors in different layers above the support structure may allow significantly increasing density of memory devices (e.g., density of memory cells in a memory array) having a given footprint area (the footprint area being defined as an area in a plane of the substrate, or a plane parallel to the plane of the substrate, i.e., the x-y plane of an example coordinate system shown in the drawings of the present disclosure), or, conversely, allows significantly reducing the footprint area of a structure with a given density of memory and/logic devices. Furthermore, by embedding at least some, but preferably all, of the storage transistors and the corresponding access transistors in the upper metal layers (i.e., in layers away from the support structure) according to at least some embodiments of the present disclosure, the peripheral circuits that control the memory operation can be hidden below the memory area to substantially reduce the memory macro array (i.e., the footprint area in the x-y plane of an example coordinate system shown in the drawings of the present disclosure). Still further, nanoribbon transistors may have improved performance compared to conventional FEOL transistors, or transistors of other architectures, and providing independent gate control to the access transistors of different memory cells may advantageously improve control of the overall memory devices while preserving the substrate area and cost.

As the foregoing illustrates, stacked 3D nanoribbon-based 2T memory cells as described herein may be used to address the scaling challenges of conventional (e.g., FEOL) memory technology and enable high density embedded memory compatible with an advanced CMOS process. Other technical effects will be evident from various embodiments described here.

In the following, some descriptions may refer to a particular S/D region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed. Furthermore, although descriptions of the present disclosure may refer to logic devices or memory cells provided in a given layer, each layer of the IC devices described herein may also include other types of devices besides logic or memory devices described herein. For example, in some embodiments, IC devices with 3D nanoribbon-based 2T memory cells (e.g., 3D nanoribbon-based 2T DRAM memory cells) as described herein may also include SRAM memory cells, or any other type of memory cells, in any of the layers.

As used herein, the term “metal layer” may refer to a layer above a support structure that includes electrically conductive interconnect structures for providing electrical connectivity between different IC components. Metal layers described herein may also be referred to as “interconnect layers” to clearly indicate that these layers include electrically conductive interconnect structures which may but does not have to be metal.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect electrical connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B), while the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

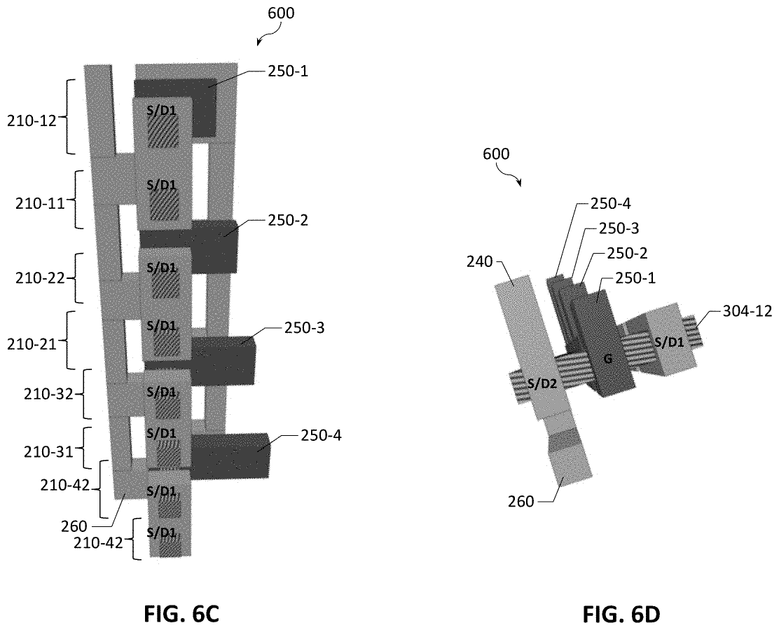

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 6A-6D, such a collection may be referred to herein without the letters, e.g., as “FIG. 6.”

The drawings are intended to show relative arrangements of the elements therein, and the device assemblies of these figures may include other elements that are not specifically illustrated (e.g., various interfacial layers). Similarly, although particular arrangements of materials are discussed with reference to the drawings, intermediate materials may be included in the devices and assemblies of these drawings. Still further, although some elements of the various device views are illustrated in the drawings as being planar rectangles or formed of rectangular solids and although some schematic illustrations of example structures are shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of one or more 3D nanoribbon-based 2T memory cells as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with 3D nanoribbon-based 2T memory cells as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

Example Layering

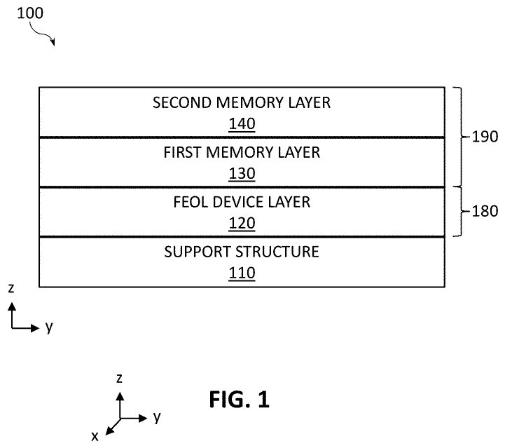

FIG. 1 provides a schematic illustration of a cross-sectional view of an example IC device 100 with multiple layers of memory and logic that may include 3D nanoribbon-based 2T memory cells, according to some embodiments of the present disclosure. As shown in FIG. 1, in general, the IC device 100 may include a support structure 110, a FEOL device layer 120, a first memory layer 130, and a second memory layer 190.

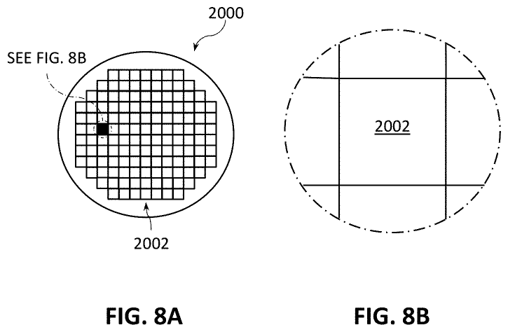

Implementations of the present disclosure may be formed or carried out on the support structure 110, which may be, e.g., a substrate, a die, a wafer or a chip. The support structure 110 may, e.g., be the wafer 2000 of FIG. 8A, discussed below, and may be, or be included in, a die, e.g., the singulated die 2002 of FIG. 8B, discussed below. The support structure 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 110 may be a printed circuit board (PCB) substrate. Although a few examples of materials from which the substrate may be formed are described here, any material that may serve as a foundation upon which a semiconductor device implementing any of the 3D nanoribbon-based 2T memory cells as described herein may be built falls within the spirit and scope of the present disclosure.

The first and second memory layers 130, 140 may, together, be seen as forming a memory array 190. As such, the memory array 190 may include storage transistors (e.g., the first transistors 210-n1, described herein) and access transistors (e.g., the second transistors 210-n2, described herein) of the 3D nanoribbon-based 2T memory cells described herein, as well as wordlines (configured to function as, e.g., row selectors) and bitlines (configured to function as, e.g., column selectors), making up memory cells. On the other hand, the FEOL layer 120 may be a compute logic layer in that it may include various logic layers, circuits, and devices (e.g., logic transistors) to drive and control a logic IC. For example, the logic devices of the compute logic layer 120 may form a memory peripheral circuit 180 to control (e.g., access (read/write), store, refresh) the memory cells of the memory array 190.

In some embodiments, the FEOL layer 120 may be provided in a FEOL and in one or more lowest BEOL layers (i.e., in one or more BEOL layers which are closest to the support structure 110), while the first memory layer 130 and the second memory layer 140 may be seen as provided in respective BEOL layers. Various BEOL layers may be, or include, metal layers. Various metal layers of the BEOL may be used to interconnect the various inputs and outputs of the logic devices in the FEOL layer 120 and/or of the memory cells in the memory layers 130, 140. Generally speaking, each of the metal layers of the BEOL may include a via portion and a trench/interconnect portion. The trench portion of a metal layer is configured for transferring signals and power along electrically conductive (e.g., metal) lines (also sometimes referred to as “trenches”) extending in the x-y plane (e.g., in the x or y directions), while the via portion of a metal layer is configured for transferring signals and power through electrically conductive vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL may include only certain patterns of conductive metals, e.g., copper (Cu), aluminum (Al), Tungsten (W), or Cobalt (Co), or metal alloys, or more generally, patterns of an electrically conductive material, formed in an insulating medium such as an interlayer dielectric (ILD). The insulating medium may include any suitable ILD materials such as silicon oxide, carbon-doped silicon oxide, silicon carbide, silicon nitride, aluminum oxide, and/or silicon oxynitride.

In other embodiments of the IC device 100, compute logic devices may be provided in a layer above the memory layers 130, 140, in between memory layers 130, 140, or combined with the memory layers 130, 140. Nanoribbon-based transistors with independent gate control as described herein may either be used as stand-alone transistors (e.g., the transistors of the FEOL 120) or included as a part of a memory cell (e.g., the storage and/or the access transistors of the memory cells of the memory layers 130, 140), and may be included in various regions/locations in the IC device 100.

The illustration of FIG. 1 is intended to provide a general orientation and arrangement of various layers with respect to one another, and, unless specified otherwise in the present disclosure, includes embodiments of the IC device 100 where portions of elements described with respect to one of the layers shown in FIG. 1 may extend into one or more, or be present in, other layers. For example, power and signal interconnects for the various components of the IC device 100 may be present in any of the layers shown in FIG. 1, although not specifically illustrated in IG. 1. Furthermore, although two memory layers 130, 140 are shown in FIG. 1, in various embodiments, the IC device 100 may include any other number of one or more of such memory layers.

Example Arrays with 2T Memory Cells

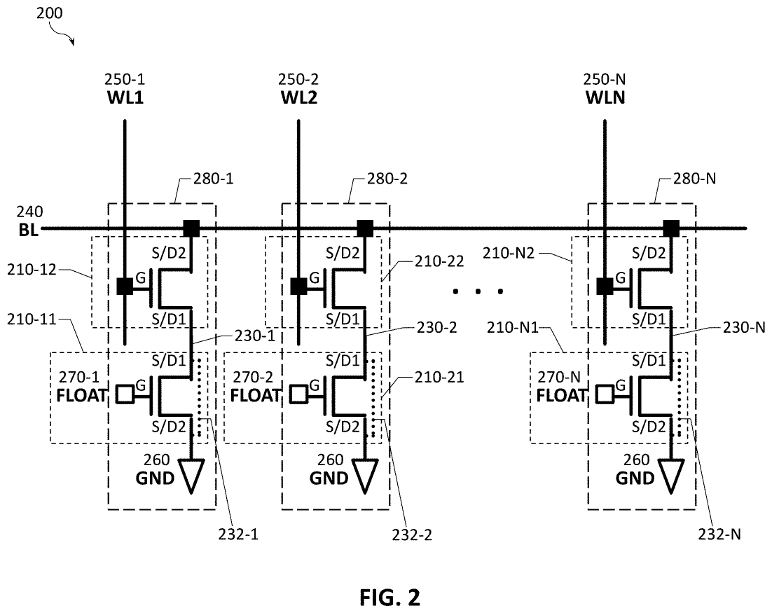

FIG. 2 is a schematic illustration of an array 200 of 2T memory cells 280, according to some embodiments of the present disclosure. The array 200 illustrates an example where memory cells 280-1, 280-2, . . . , and 280-N are shown, thus showing an example of N memory cells 280, where N is an integer greater than 2 for this example. However, in general, the array 200 may include any number N of the memory cells 280, where N is an integer equal to or greater than 2.

In the following, the notation of using a given reference numeral with either “1” or “2” after a dash is supposed to refer to different instances of analogous elements included in different memory cells. For example, the first memory cell 280 is denoted as a memory cell 280-1, the second memory cell is denoted as a memory cell 280-2, and, in general, a memory cell n (where n is an integer specifying one memory cell 280 of the plurality of N memory cells 280) is denoted as a memory cell 280-n. In another example, a WL 250 coupled to the first memory cell 280-1 is denoted as a WL 250-1, a WL 250 coupled to the second memory cell 280-2 is denoted as a WL 250-2, and, in general, a WL 250 for the memory cell n is denoted as a WL 250-n. On the other hand, the notation of using a given reference numeral with either “n1” or “n2” after a dash is supposed to refer to different instances of analogous elements included in a given memory cell 280-n. For example, the first transistor 210 of the first memory cell 280-1 is denoted as a first transistor 210-11, while the second transistor 210 of the first memory cell 280-1 is denoted as a second transistor 210-12, the first transistor 210 of the second memory cell 280-2 is denoted as a first transistor 210-21, while the second transistor 210 of the second memory cell 280-2 is denoted as a second transistor 210-22, and, in general, the first transistor 210 of the memory cell 280-n is denoted as a first transistor 210-n1, while the second transistor 210 of the memory cell 280-n is denoted as a second transistor 210-n2.

As shown in FIG. 2, each memory cell 280-n may include a first transistor 210-n1 and a second transistor 210-n2 (i.e., each memory cell 280-n is a 2T memory cell). Each of the transistors 210 may be a FET, having a gate terminal, a source terminal, and a drain terminal. In FIG. 2, the gate terminal of each transistor 210 shown is labeled as “G,” while the first and second S/D terminals are labeled as S/D1 and S/D2 (where, for each transistor 210, one of S/D1 and S/D2 is a source terminal and the other one is a drain terminal). In the following, the terms “terminal” and “electrode” may be used interchangeably. Furthermore, for S/D terminals, the terms “terminal” and “region” may be used interchangeably. Still further, the terms “gate terminal” and “gate stack” may be used interchangeably.

As shown in FIG. 2, for a given 2T memory cell 280-n, one of the S/D terminals of the first transistor 210-n1 (e.g., the terminal S/D1 of the first transistor) may be coupled to one of the S/D terminals of the second transistor 210-n2 (e.g., the terminal S/D1 of the second transistor), e.g., using an electrically conductive structure 230-n. The second terminal S/D2 of the second transistor 210-n2 may be coupled to a BL 240, while the gate stack G of the second transistor 210-n2 may be coupled to a WL 250-n. In the array 200 of N memory cells 280, the terminals S/D2 of the second transistors 210-n2 of different memory cells 280-n may be coupled to a single, shared BL, as shown in FIG. 2 with the BL 240 being coupled to the S/D2 of the second transistor 210-12 of the first memory cell 280-1, the S/D2 of the second transistor 210-22 of the second memory cell 280-2, and so on, until the S/D2 of the second transistor 210-N2 of the Nth memory cell 280-N. On the other hand, in the array 200 of N memory cells 280, the gate stacks G of the second transistors 210-n2 of different memory cells 280-n may be coupled to respective (i.e., different) WLs, as shown in FIG. 2 with the WL1 250-1 being coupled to the gate G of the second transistor 210-12 of the first memory cell 280-1, the WL2 250-2 being coupled to the gate G of the second transistor 210-22 of the second memory cell 280-2, and so on, until the WLN 250-N being coupled to the gate G of the second transistor 210-N2 of the Nth memory cell 280-N.

As further shown in FIG. 2, the second terminal S/D2 of the first transistor 210-n1 may be coupled to a ground potential 260, and the gate stack G of the first transistor 210-n1 may be left electrically floating (i.e., not coupled to any electrical potential), the latter as illustrated in FIG. 2 as a FLOAT gate 270-n. Although FIG. 2 illustrates a separate ground potential 260 for each of the memory cells 280, in other embodiments, the ground potential 260 may be shared among two or more memory cells 280.

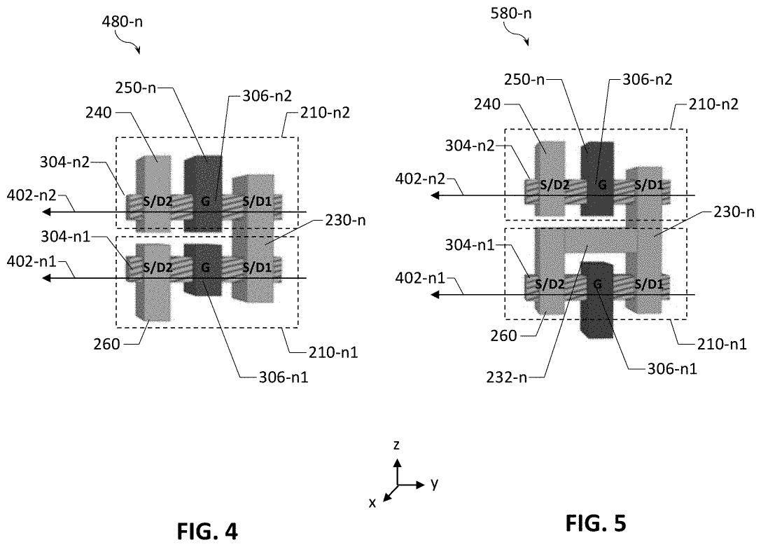

By configuring the first and second transistors 210 of each memory cell 280-n as described above, the first transistor 210-n1 may be used as a storage transistor, and the second transistor 210-n2 may be used as an access transistor. An example of such a memory cell is shown as a memory cell 480 illustrated in FIG. 4.

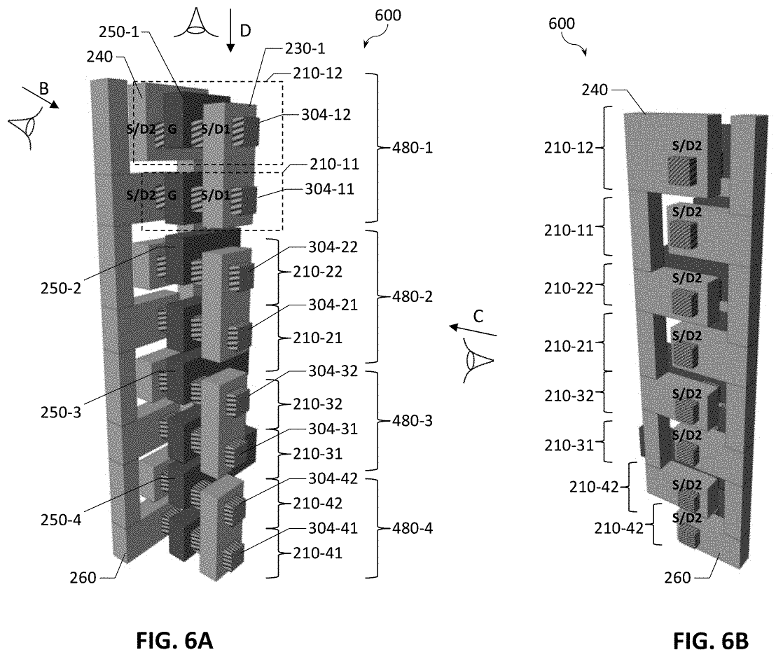

In some embodiments of the memory array 200, the first and second S/D terminals, S/D1 and S/D2, of the first transistor 210-n1 may be coupled to one another, e.g., using an electrically conductive structure 232-n. Since the second terminal S/D2 of the first transistor 210-n1 is coupled to the ground potential 260, the coupling of the electrically conductive structure 232-n means that the first terminal S/D1 of the first transistor 210-n1 is also coupled to the ground potential 260. Furthermore, since the first terminal S/D1 of the first transistor 210-n1 is coupled to the first terminal S/D1 of the second transistor 210-n2, the coupling of the electrically conductive structure 230-n means that the first terminal S/D1 of the second transistor 210-n2 is also coupled to the ground potential 260. Thus, in such embodiments, each of 1) the first terminal S/D1 of the first transistor 210-n1, 2) the second terminal S/D2 of the first transistor 210-n1, and 3) the first terminal S/D1 of the second transistor 210-n2 may be coupled to the ground potential 260 (which may be different or shared ground potential sources). An example of such a memory cell is shown as a memory cell 580 illustrated in FIG. 5. An example of a memory cell where the first and second S/D terminals, S/D1 and S/D2, of the first transistor 210-n1 are not coupled to one another is shown as a memory cell 480 illustrated in FIG. 4.

Each of the BL 240, the WLs 250, the electrically conductive structures 230, and, the optional electrically conductive structures 232, as well as intermediate elements coupling these lines to various transistor terminals described herein, may be formed of any suitable electrically conductive material, which may include an alloy or a stack of multiple electrically conductive materials. In some embodiments, such electrically conductive materials may include one or more metals or metal alloys, with metals such as copper, ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

As described above, each of the storage transistor 210-n1 and the access transistor 210-n2 may be a nanoribbon-based transistor (or, simply, a nanoribbon transistor, e.g., a nanowire transistor). In a nanoribbon transistor, a gate stack that may include a stack of one or more gate electrode materials (e.g., gate electrode metals) and, optionally, a stack of one or more gate dielectrics may be provided around a portion of an elongated semiconductor structure called “nanoribbon”, potentially forming a gate on all sides of the nanoribbon (although, in some implementations, one or more sides of a nanoribbon may not be wrapped by a gate stack). The portion of the nanoribbon around which the gate stack wraps around is referred to as a “channel” or a “channel portion.” A semiconductor material of which the channel portion of the nanoribbon is formed is commonly referred to as a “channel material.” A source region and a drain region are provided on the opposite ends of the nanoribbon, on either side of a gate stack, forming, respectively, a source and a drain of a transistor. Wrap-around or all-around gate transistors, such as nanoribbon and nanowire transistors, may provide advantages compared to other transistors having a non-planar architecture, such as FinFETs.

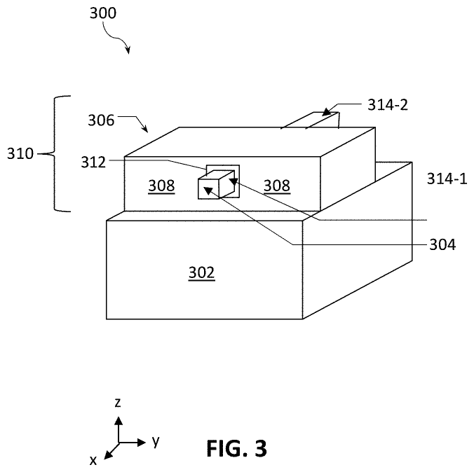

FIG. 3 is a perspective view of an IC structure 300 with an example nanoribbon-based FET 310 that may be used as any, or both, of the transistors of a 2T memory cell, according to some embodiments of the present disclosure. In various embodiments, the transistor 310 may be used as any of the transistors 210 of the 2T memory cells 280, of the 2T memory cell 480, or of the 2T memory cell 580, described herein.

The arrangement 300 shown in FIG. 3 (and other figures of the present disclosure) is intended to show relative arrangements of some of the components therein, and the arrangement 300, or portions thereof, may include other components that are not illustrated (e.g., electrical contacts to the source and the drain of the transistor 310, additional layers such as a spacer layer around the gate electrode of the transistor 310, etc.). For example, although not specifically illustrated in FIG. 3, a dielectric spacer may be provided between the source electrode and the gate stack as well as between the transistor drain electrode and the gate stack of the transistor 310 in order to provide electrical isolation between the source, gate, drain electrodes. In another example, although not specifically illustrated in FIG. 3, at least portions of the transistor 310 may be surrounded in an insulator material, such as any suitable ILD material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 310 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

Turning to the details of FIG. 3, the transistor 310 may include a channel material formed as a nanoribbon 304 made of one or more semiconductor materials, the nanoribbon 304 provided over a base 302. In some embodiments, the base 302 may be the support structure 110, described above. In some embodiments, a layer of oxide material (not specifically shown in FIG. 3) may be provided between the base 302 and a gate stack 306. In the embodiments of the 3D nanoribbon-based memory cells with the transistors 310 being provided in the further BEOL layers (i.e., not right above the support structure 110), the base 302 may be a layer in which another nanoribbon transistor 310 is provided (not specifically shown in FIG. 3).

The nanoribbon 304 may take the form of a nanowire or nanoribbon, for example. Although the nanoribbon 304 illustrated in FIG. 3 is shown as having a square cross-section, the nanoribbon 304 may instead have a cross-section that is rectangular but not square, a cross-section that is rounded at corners or otherwise irregularly shaped, and the gate stack 306 may conform to the shape of the nanoribbon 304. In use, the all-around-gate transistor 310 may form conducting channels on more than three “sides” of the nanoribbon 304, potentially improving performance relative to FinFETs. Furthermore, although FIG. 3, as well as FIGS. 4-6, depict embodiments in which the longitudinal axis of the nanoribbon 304 runs substantially parallel to a plane of the base 302, this need not be the case; in other embodiments, the nanoribbon 304 may be oriented, e.g., “vertically” so as to be perpendicular to a plane of the base 302.

In some embodiments, the channel material of the nanoribbon 304 may be composed of semiconductor material systems including, for example, N-type or P-type materials systems. In some embodiments, the channel material of the nanoribbon 304 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material of the nanoribbon 304 may include a combination of semiconductor materials. In some embodiments, the channel material of the nanoribbon 304 may include a monocrystalline semiconductor, such as silicon (Si) or germanium (Ge). In some embodiments, the channel material of the nanoribbon 304 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 310 is an NMOS transistor), the channel material of the nanoribbon 304 may advantageously include a III-V material having a high electron mobility, such as, but not limited to InGaAs, InP, InSb, and InAs. For some such embodiments, the channel material of the nanoribbon 304 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel material of the nanoribbon 304 may be an intrinsic III-V material, i.e., a III-V semiconductor material not intentionally doped with any electrically active impurity. In alternate embodiments, a nominal impurity dopant level may be present within the channel material of the nanoribbon 304, for example to further fine-tune a threshold voltage Vt, or to provide HALO pocket implants, etc. Even for impurity-doped embodiments however, impurity dopant level within the channel material of the nanoribbon 304 may be relatively low, for example below 10¹⁵ dopant atoms per cubic centimeter (cm⁻³), and advantageously below 10¹³ cm⁻³.

For some example P-type transistor embodiments (i.e., for the embodiments where the transistor 310 is a PMOS transistor), the channel material of the nanoribbon 304 may advantageously be a group IV material having a high hole mobility, such as, but not limited to Ge or a Ge-rich SiGe alloy. For some example embodiments, the channel material of the nanoribbon 304 may have a Ge content between 0.6 and 0.9, and advantageously may be at least 0.7. In some embodiments with highest mobility, the channel material of the nanoribbon 304 may be intrinsic III-V (or IV for P-type devices) material and not intentionally doped with any electrically active impurity. In alternate embodiments, one or more a nominal impurity dopant level may be present within the channel material of the nanoribbon 304, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³.

In some embodiments, the channel material of the nanoribbon 304 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 304 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 304 may have a thickness between about 5 and 75 nanometers, including all values and ranges therein. In some embodiments, a thin-film channel material may be deposited at relatively low temperatures, which allows depositing the channel material within the thermal budgets imposed on back end fabrication to avoid damaging other components, e.g., front end components such as the logic devices.

A gate stack 306 including a gate electrode material 308 and, optionally, a gate dielectric material 312, may wrap entirely or almost entirely around a portion of the nanoribbon 304 as shown in FIG. 3, with the active region (channel region) of the channel material of the transistor 310 corresponding to the portion of the nanoribbon 304 wrapped by the gate stack 306. In particular, the gate dielectric material 312 may wrap around a transversal portion of the nanoribbon 304 and the gate electrode material 308 may wrap around the gate dielectric material 312. In some embodiments, the gate stack 306 may fully encircle the nanoribbon 304. In other embodiments, the gate stack 306 may not be included on one or more sides of the nanoribbon 304, e.g., in some embodiments, the gate stack 306 may not be included on one of the sidewalls of the nanoribbon 304, e.g., in forksheet transistor implementations.

The gate electrode material 308 may include at least one P-type work function metal or N-type work function metal, depending on whether the transistor 310 is a P-type metal-oxide-semiconductor (PMOS) transistor or an N-type metal-oxide-semiconductor (NMOS) transistor (P-type work function metal used as the gate electrode material 308 when the transistor 310 is a PMOS transistor and N-type work function metal used as the gate electrode material 308 when the transistor 310 is an NMOS transistor). For a PMOS transistor, metals that may be used for the gate electrode material 308 may include, but are not limited to, ruthenium, palladium, platinum, cobalt, nickel, and conductive metal oxides (e.g., ruthenium oxide). For an NMOS transistor, metals that may be used for the gate electrode material 308 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 308 may include a stack of two or more metal layers, where one or more metal layers are work function metal layers and at least one metal layer is a fill metal layer. Further layers may be included next to the gate electrode material 308 for other purposes, such as to act as a diffusion barrier layer or/and an adhesion layer.

In some embodiments, the gate dielectric material 312 may include one or more high-k dielectrics including any of the materials discussed herein with reference to the insulator material that may surround portions of the transistor 310. In some embodiments, an annealing process may be carried out on the gate dielectric material 312 during manufacture of the transistor 310 to improve the quality of the gate dielectric material 312. The gate dielectric material 312 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 306 may be surrounded by a gate spacer, not shown in FIG. 3. Such a gate spacer would be configured to provide separation between the gate stack 306 and source/drain contacts of the transistor 310 and could be made of a low-k dielectric material, some examples of which have been provided above. A gate spacer may include pores or air gaps to further reduce its dielectric constant.

In some embodiments, when the transistor 310 is a storage transistor (e.g., any of the first transistors 210-n1, described herein), the gate dielectric 312 may be replaced with, or complemented with a layer of a ferroelectric material. Such a ferroelectric material may include one or more materials which exhibit sufficient ferroelectric or antiferroelectric behavior even at thin dimensions. Some examples of such materials known at the moment include hafnium zirconium oxide (HfZrO, also referred to as HZO), silicon-doped (Si-doped) hafnium oxide, germanium-doped (Ge-doped) hafnium oxide, aluminum-doped (Al-doped) hafnium oxide, and yttrium-doped (Y-doped) hafnium oxide. However, in other embodiments, any other materials which exhibit ferroelectric or antiferroelectric behavior at thin dimensions may be used to replace, or to complement, the gate dielectric 312 when the transistor 310 is a storage transistor (e.g., any of the first transistors 210-n1, described herein), and are within the scope of the present disclosure. The ferroelectric material included in the gate stack 306 when the transistor 310 is a storage transistor (e.g., any of the first transistors 210-n1, described herein), may have a thickness that may, in some embodiments, be between about 0.5 nanometers and 10 nanometers, including all values and ranges therein (e.g., between about 1 and 8 nanometers, or between about 0.5 and 5 nanometers).

In still further embodiments, the transistor 310 may be configured to store the logic state by including various other materials, e.g., chalcogenide materials and other materials that can change state either under the influence of electric or magnetic fields, or both. Thus, in general, the transistor 310 may be configured to store the logic state using various forms of state storage mechanisms, such as charge storage, magnetic field, resistance change, or material properties that can be electrically or magnetically controlled that can modulate the state storage mechanism.

As further shown in FIG. 3, the nanoribbon 304 may include a source region and a drain region on either side of the gate stack 306, thus realizing a transistor. As is well known in the art, source and drain regions are formed for the gate stack of each MOS transistor. As described above, the source and drain regions of a transistor are interchangeable, and a nomenclature of a first S/D region and a second S/D region of an access transistor has been introduced for use in the present disclosure. In FIG. 3, reference numeral 314-1 is used to label the first S/D region, SD/1, and reference numeral 314-2 is used to label the second S/D region, S/D2, of the transistor 310.

The S/D regions 314 of the transistor 310 may generally be formed using either an implantation/diffusion process or an etching/deposition process. In the former process, dopants such as boron, aluminum, antimony, phosphorous, or arsenic may be ion-implanted into the nanoribbon 304 to form the source and drain regions. An annealing process that activates the dopants and causes them to diffuse further into the nanoribbon 304 may follow the ion implantation process. In the latter process, portions of the nanoribbon 304 may first be etched to form recesses at the locations of the future S/D regions 314. An epitaxial deposition process may then be carried out to fill the recesses with material that is used to fabricate the S/D regions 314. In some implementations, the S/D regions 314 may be fabricated using a silicon alloy such as silicon germanium or silicon carbide. In some implementations the epitaxially deposited silicon alloy may be doped in situ with dopants such as boron, arsenic, or phosphorous. In further embodiments, the S/D regions 314 may be formed using one or more alternate semiconductor materials such as germanium or a group III-V material or alloy. And in further embodiments, one or more layers of metal and/or metal alloys may be used to form the S/D regions 314.

In some embodiments, the transistor 310 may have a gate length (i.e., a distance between the first and second S/D regions 314), a dimension measured along the nanoribbon 304, between about 5 and 40 nanometers, including all values and ranges therein (e.g., between about 22 and 35 nanometers, or between about 20 and 30 nanometers). In some embodiments, an area of a transversal cross-section of the nanoribbon 304 may be between about 25 and 10000 square nanometers, including all values and ranges therein (e.g., between about 25 and 1000 square nanometers, or between about 25 and 500 nanometers). In some embodiments, a width of the nanoribbon 304 (i.e., a dimension measured in a plane parallel to the base 302 and in a direction perpendicular to the long axis of the nanoribbon 304, e.g., along the y-axis of the example coordinate system shown in FIG. 3) may be at least about 3 times larger than a height of the nanoribbon 304 (i.e., a dimension measured in a plane perpendicular to the base 302, e.g., along the z-axis of the example coordinate system shown in FIG. 3), including all values and ranges therein, e.g., at least about 4 times larger, or at least about 5 times larger.

First Example of a 3D Nanoribbon-Based 2T Memory Cell

The 2T memory cells 280 may be implemented by using the transistors 210 as the nanoribbon-based transistors 310. One example of such a memory cell is shown in FIG. 4, providing a perspective view of a first example of a 3D nanoribbon-based 2T memory cell 480-n, according to some embodiments of the present disclosure. The memory cell 480-n is a first example of any memory cell 280-n of the N 2T memory cells 280 shown in FIG. 2. FIG. 4 illustrates some elements with reference numerals which are the same as in FIGS. 2 and 3 to indicate elements which are the same/analogous to those described with reference to FIGS. 2 and 3, which descriptions are applicable to the memory cell 480-n. In the interests of brevity, these descriptions are not repeated, and only the differences or unique features of the arrangement of the memory cell 480-n are described.

As shown in FIG. 4, the first and second transistors 210-n1 and 210-n2 may be implemented along different nanoribbons, namely, along the first and second nanoribbons 304-n1 and 304-n2, respectively. In some embodiments, the second nanoribbon 304-n2 may be stacked above the first nanoribbon 304-n1, so that the first nanoribbon 304-n1 is between the support structure 110 (e.g., the base 302) and the second nanoribbon 304-n2, as shown in FIG. 4 and in FIGS. 6A-6D, described below (the support structure 110 or base 302 are not specifically shown in order to not clutter these drawings, but it would be below the drawing of the memory cells shown in these figures). Thus, both nanoribbons 304 may extend in a direction substantially parallel to the support structure 110, and, thus, substantially parallel to one another. Arrows 402-n1 and 402-n2, shown in FIG. 4, illustrate, respectively, the long axis of the first nanoribbon 304-n1 and the long axis of the second nanoribbon 304-n2.

As further shown in FIG. 4, for the first transistor 210-n1, the gate stack 306-n1 may not be coupled to anything, thus left to be electrically floating. On the different sides of the gate stack 306-n1, first and second S/D regions, S/D1 and S/D2, are provided within the first nanoribbon 304-n1. For the second transistor 210-n2, the gate stack 306-n2 may be coupled to, or be formed by the WL 250-n associated with the memory cell 480-n, and on the different sides of the gate stack 306-n2, first and second S/D regions, S/D1 and S/D2, are provided within the second nanoribbon 304-n2. FIG. 4 illustrates the electrically conductive structure 230-n that coupled the S/D1 of the first transistor 210-n1 and the S/D1 of the second transistor 210-n2, as is described above with reference to FIG. 2. FIG. 4 further illustrates that the S/D2 of the first transistor 210-n1 is coupled to the ground potential 260, while the S/D2 of the second transistor 210-n2 is coupled to the BL 240, as is described above with reference to FIG. 2.

Second Example of a 3D Nanoribbon-Based 2T Memory Cell

Another example of a 2T memory cell 280 implemented by using the transistors 210 as the nanoribbon-based transistors 310 is shown in FIG. 5, providing a perspective view of a second example of a 3D nanoribbon-based 2T memory cell 580-n, according to some embodiments of the present disclosure. The memory cell 580-n is a second example of any memory cell 280-n of the N 2T memory cells 280 shown in FIG. 2. Similar to FIG. 4, FIG. 5 illustrates some elements with reference numerals which are the same as in FIGS. 2-4 to indicate elements which are the same/analogous to those described with reference to FIGS. 2-4, which descriptions are applicable to the memory cell 580-n. In the interests of brevity, these descriptions are not repeated, and only the differences or unique features of the arrangement of the memory cell 580-n are described.

The memory cell 580-n is substantially the same as the memory cell 480-n, except that, in addition to the elements described with reference to FIG. 4, the memory cell 580-n further includes the electrically conductive structure 232-n, configured to provide electrical coupling between the S/D1 and the S/D2 of the first transistor 210-n1, as described with reference to the optional embodiment of FIG. 2. As shown in FIG. 5, in some embodiments, the electrically conductive structure 232-n may be coupled to the electrically conductive structure 230-n, thus ensuring that each of the S/D1 of the first transistor 210-n1, S/D2 of the first transistor 210-n1, and S/D1 of the second transistor 210-n2 is coupled to the ground potential 260.

Example 3D Arrays of 3D Nanoribbon-Based 2T Memory Cells

A plurality of the 3D nanoribbon-based 2T memory cells such as the cells 480-n and/or 580-n, described above, may be arranged in arrays. One example of a 3D array is shown in FIGS. 6A-6D, providing different perspective views of an example 3D memory array 600 with a plurality of stacked 3D nanoribbon-based 2T memory cells 480-n of FIG. 4, according to some embodiments of the present disclosure. Four different perspective views are shown in an attempt to bring clarity of the arrangement of the device 600, where different elements may be labeled in different views. It should be noted that not all elements shown in FIGS. 6A-6D are labeled with reference numerals in order to not clutter the drawings. For example, although 4 memory cells 480 are shown in each of FIGS. 6A-6D, these memory cells are only labeled individually in FIG. 6A as memory cells 480-1, 480-2, 480-3, and 480-4. FIGS. 6A-6D illustrate some elements with reference numerals which are the same as in FIGS. 2-4 to indicate elements which are the same/analogous to those described with reference to FIGS. 2-4, which descriptions are applicable to the memory cell 480-n of the array 600. In the interests of brevity, these descriptions are not repeated, and only the differences or unique features of the array 600 of the memory cell 480-n are described.

The device 600 is an example of the IC device 200, where each of the memory cells 280-n is implemented as the memory cell 480-n, described above, and where N=4. The device 600 illustrates an example where different memory cells 480-n are stacked above one another above the support structure. Such an arrangement may help realize a small x-y footprint of the array 600.

As shown in FIGS. 6A-6D, the BL 240 is shared among the memory cells 480-1 through 480-4 by being coupled to the S/D2 of the second transistor 210-12 through 210-42 of the memory cells 480-1 through 480-4. Similarly, the ground potential connection 260 may also be shared among the memory cells 480-1 through 480-4 by being coupled to the S/D2 of the first transistor 210-11 through 210-41 of the memory cells 480-1 through 480-4. On the other hand, the WL 250 is an individual connection to each of the memory cells 480-1 through 480-4, shown in FIGS. 6A-6D as the WL 250-1 coupled to the gate stack of the second transistor 210-12 of the memory cell 480-1, the WL 250-2 coupled to the gate stack of the second transistor 210-22 of the memory cell 480-2, the WL 250-3 coupled to the gate stack of the second transistor 210-32 of the memory cell 480-3, and the WL 250-4 coupled to the gate stack of the second transistor 210-42 of the memory cell 480-4.

As shown in FIGS. 6A-6D, when the nanoribbons 304 extend in a direction substantially parallel to the support structure 110, the shared BL, e.g., the BL 240, may then extend in a direction substantially perpendicular to the support structure 110. Furthermore, in some embodiments, for a set of access transistors stacked above one another, the WLs 250-1 through 250-4 may be arranged in a staircase-like manner (e.g., as can be seen in the view of FIG. 6D, i.e., where they are provided over different portions of the support structure 110) to enable easy and compact individual gate control of the access transistors of the memory cells 480 that are stacked above one another.

The device 600 illustrates how a memory array, e.g., a DRAM array, may be created in a NAND-like fashion. The topology illustrated in FIGS. 6A-6D creates a vertical stack of memory cells 480 where some of the bitlines (e.g., the BL 240) can be shorted (i.e., electrically coupled to one another, or be a shared BL) and the respective wordlines 250 for the different memory cells of the vertical stack can be created in a staircase fashion. Such a vertical topology can advantageously create a relatively small bitline capacitance and footprint. With such an approach, a 3D memory array with a large number of vertical memory cells may be fabricated at very low cost.

Although not specifically shown in the present drawings, a memory array similar to the memory array 600 may be formed with the memory cells 580-n, described above. In some embodiments, such a memory array could be substantially the same as the array 600 shown in FIGS. 6A-6D, except that each memory cell would further include the electrically conductive structure 232-n as described above.

Example Fabrication Method

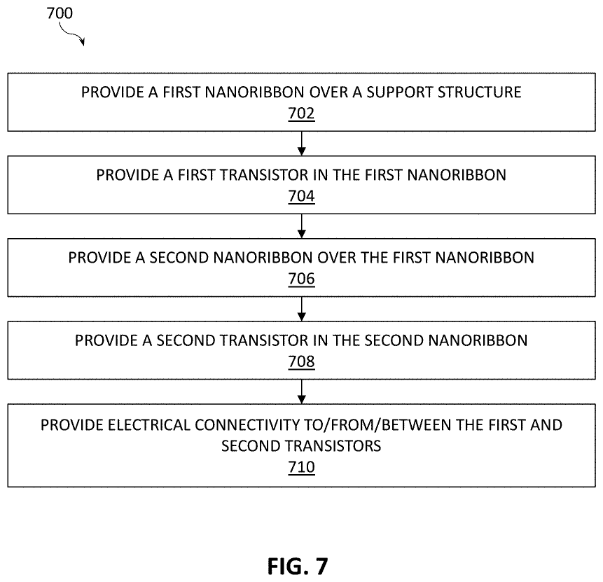

FIG. 7 is a method 700 for fabricating one or more 3D nanoribbon-based 2T memory cells, according to some embodiments of the present disclosure. The method 700 may be used to fabricate any embodiments of one or more of the 3D nanoribbon-based 2T memory cells 480-n, 580-n, described herein.

Although the operations of the method 700 are illustrated once each and in a particular order, the operations may be performed in any suitable order and repeated as desired. For example, one or more operations may be performed in parallel to manufacture, substantially simultaneously, multiple 3D nanoribbon-based 2T memory cells as described herein. In another example, the operations of the method 700 may be performed in a different order to reflect the structure of a particular device in which one or more 3D nanoribbon-based 2T memory cells as described herein will be included, and/or to be in accordance with manufacturing capabilities, requirements, and limitations.

In addition, the example manufacturing method 700 may include other operations not specifically shown in FIG. 7, such as various cleaning or planarization operations as known in the art. For example, in some embodiments, the support structure 110, as well as layers of various other materials and structures subsequently deposited thereon, may be cleaned prior to, after, or during any of the processes of the method 700 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the method 700 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

The method 700 may include a process 702 that includes providing a first nanoribbon, e.g., the nanoribbon 304-1, over a support structure, e.g., the support structure 110 or the base 302, as described herein.

The method 700 may include a process 704 that includes providing a first transistor in the first nanoribbon, e.g., the transistor 210-1 in the nanoribbon 304-1, as described herein.

The method 700 may include a process 706 that includes providing a second nanoribbon over the first nanoribbon, e.g., providing the nanoribbon 304-2 stacked over the nanoribbon 304-1, as described herein.

The method 700 may include a process 708 that includes providing a second transistor in the second nanoribbon, e.g., the transistor 210-2 in the nanoribbon 304-2, as described herein.

The method 700 may include a process 710 that includes providing electrical connectivity to/from/between the first and the second transistors, e.g., between the transistor 210-1 and 210-2. In some embodiments, the process 710 may include providing one or more of the BL 240, the WLs 250-n, the electrically conductive structures 230-n and 232-n, the ground potential connection 260, as described herein.

Variations and Implementations

Various device assemblies illustrated in FIGS. 1-6 do not represent an exhaustive set of IC devices with one or more 3D nanoribbon-based 2T memory cells as described herein, but merely provide examples of such devices/structures/assemblies. In particular, the number and positions of various elements shown in FIGS. 1-6 is purely illustrative and, in various other embodiments, other numbers of these elements, provided in other locations relative to one another may be used in accordance with the general architecture considerations described herein. For example, in some embodiments, logic devices, e.g., implemented as/using the transistors 310 or implemented as/using transistors of any other architecture, may be included in any of the IC devices shown in FIGS. 1-6, either in the same or separate metal layers from those in which the memory cells are shown.

Example Electronic Devices

Arrangements with one or more 3D nanoribbon-based 2T memory cells as disclosed herein may be included in any suitable electronic device. FIGS. 8-11 illustrate various examples of devices and components that may include one or more 3D nanoribbon-based 2T memory cells, e.g., 3D arrays of such cells, as disclosed herein.

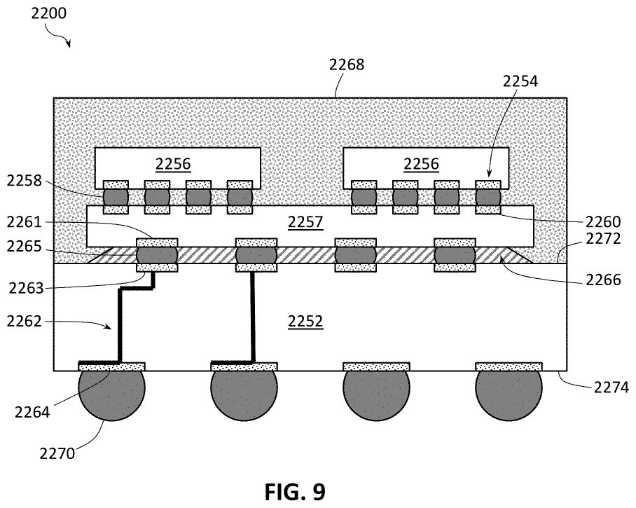

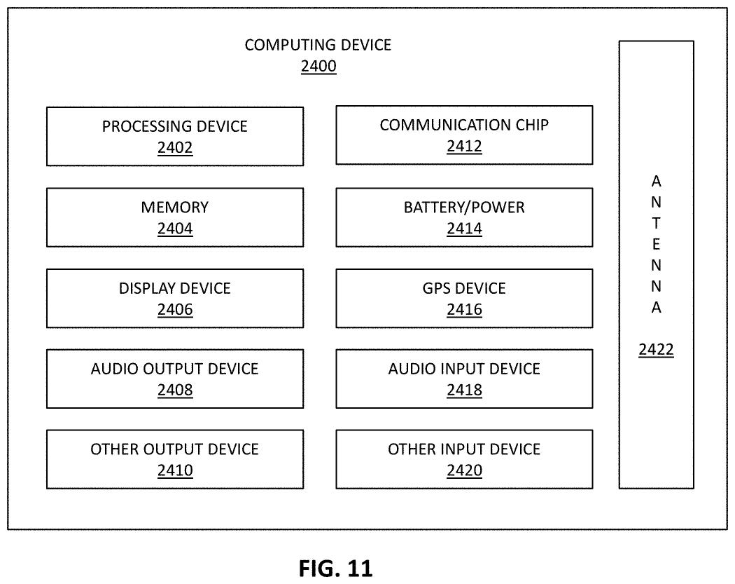

FIGS. 8A-8B are top views of a wafer 2000 and dies 2002 that may include one or more 3D nanoribbon-based 2T memory cells in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 9. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more 3D nanoribbon-based 2T memory cells as described herein, and/or one or more memory arrays with 3D nanoribbon-based 2T memory cells as described herein). After the fabrication of the semiconductor product is complete (e.g., after manufacture of one or more layers of the 3D nanoribbon-based 2T memory cells as described herein (e.g. any embodiment of the memory array 190 of the IC device 100, e.g. including an array of any of the memory cells described herein), the wafer 2000 may undergo a singulation process in which each of the dies 2002 is separated from one another to provide discrete “chips” of the semiconductor product. In particular, devices that include one or more 3D nanoribbon-based 2T memory cells as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a DRAM device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 11) or other logic that is configured to store information in the memory devices or execute instructions stored in the memory array.

FIG. 9 is a side, cross-sectional view of an example IC package 2200 that may include one or more 3D nanoribbon-based 2T memory cells in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 9 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 9 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

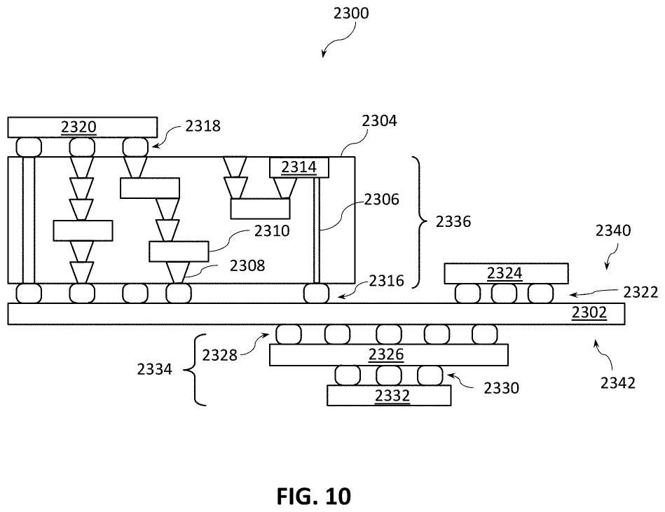

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 9 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 10.

The dies 2256 may take the form of any of the embodiments of the die 2002 discussed herein (e.g., may include any of the embodiments of the 3D nanoribbon-based 2T memory cells as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more 3D nanoribbon-based 2T memory cells, e.g., as discussed above; in some embodiments, at least some of the dies 2256 may not include any 3D nanoribbon-based 2T memory cells.

The IC package 2200 illustrated in FIG. 9 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 9, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 10 is a cross-sectional side view of an IC device assembly 2300 that may include components having one or more 3D nanoribbon-based 2T memory cells in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more 3D nanoribbon-based 2T memory cells and/or one or more 3D memory arrays with 3D nanoribbon-based 2T memory cells in accordance with any of the embodiments disclosed herein; e.g., any of the IC packages discussed below with reference to the IC device assembly 2300 may take the form of any of the embodiments of the IC package 2200 discussed above with reference to FIG. 9 (e.g., may include one or more 3D nanoribbon-based 2T memory cells provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 10 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 10), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 8B), an IC device, or any other suitable component. In particular, the IC package 2320 may include one or more 3D nanoribbon-based 2T memory cells as described herein. Although a single IC package 2320 is shown in FIG. 10, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 10, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 10 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 11 is a block diagram of an example computing device 2400 that may include one or more components with one or more 3D nanoribbon-based 2T memory cells in accordance with any of the embodiments disclosed herein. For example, any suitable ones of the components of the computing device 2400 may include a die (e.g., the die 2002 (FIG. 8B)) including one or more 3D nanoribbon-based 2T memory cells in accordance with any of the embodiments disclosed herein. Any of the components of the computing device 2400 may include an IC package 2200 (FIG. 9). Any of the components of the computing device 2400 may include an IC device assembly 2300 (FIG. 10).

A number of components are illustrated in FIG. 11 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 11, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include eDRAM, e.g. a 3D array of 3D nanoribbon-based 2T memory cells as described herein, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

Select Examples

The following paragraphs provide various examples of the embodiments disclosed herein.

Example 1 provides memory device (or, more generally, an IC device) that includes a support structure (e.g., a substrate, a chip, or a wafer). The memory device further includes a memory cell that includes a first transistor (e.g., the transistor 210-n1, shown in FIGS. 4-5) and a second transistor (e.g., the transistor 210-n2, shown in FIGS. 4-5). The first transistor has a first S/D region and a second S/D region in a first semiconductor nanoribbon (where, in general, the term “nanoribbon” refers to an elongated semiconductor structure such as a nanoribbon or a nanowire, having a long axis parallel to the support structure), where the first nanoribbon (e.g., the nanoribbon 304-n1, shown in FIGS. 4-5) extends in a direction substantially parallel to the support structure. The second transistor (e.g., the transistor 210-n2, shown in FIGS. 4-5) has a first S/D region and a second S/D region in a second semiconductor nanoribbon (e.g., the nanoribbon 304-n2, shown in FIGS. 4-5), where the second nanoribbon extends in a direction substantially parallel to the support structure and is stacked above the first nanoribbon so that the first nanoribbon is between the support structure and the second nanoribbon. The first transistor is configured to store a memory state of the memory cell. The second transistor is configured to control access to the memory cell.

Example 2 provides the memory device according to example 1, where the first S/D region of the first transistor is coupled to the first S/D region of the second transistor (e.g., via the electrically conductive structure 230-n, shown in FIGS. 4-5).

Example 3 provides the memory device according to examples 1 or 2, where the second S/D region of the first transistor is coupled to a ground potential.

Example 4 provides the memory device according to example 3, where each of the first S/D region of the first transistor and the first S/D region of the second transistor is coupled to the ground potential.

Example 5 provides the memory device according to any one of the preceding examples, where a gate stack of the first transistor is electrically floating (i.e., is not connected to any electrical potential).

Example 6 provides the memory device according to any one of the preceding examples, where the second S/D region of the second transistor is coupled to a bitline, and the bitline extends in a direction that is substantially perpendicular to the support structure.

Example 7 provides the memory device according to example 6, where the memory cell is a first memory cell, and the memory device further includes a second memory cell. The second memory cell includes a third transistor, having a first S/D region and a second S/D region in a third semiconductor nanoribbon, where the third nanoribbon extends in a direction substantially parallel to the support structure and is stacked above the second nanoribbon so that the second nanoribbon is between the first nanoribbon and the third nanoribbon, and a fourth transistor, having a first S/D region and a second S/D region in a fourth semiconductor nanoribbon, where the fourth nanoribbon extends in a direction substantially parallel to the support structure and is stacked above the third nanoribbon so that the third nanoribbon is between the second nanoribbon and the fourth nanoribbon. The second S/D region of the fourth transistor is coupled to the bitline (i.e., to the same bitline that the second S/D region of the second transistor is coupled to, thus the second S/D region of the second transistor is coupled to the second S/D region of the fourth transistor, or, in other words, the second transistor and the fourth transistor are coupled to a single/shared bitline).

Example 8 provides the memory device according to example 7, where the third transistor is configured to store a memory state of the second memory cell, and the fourth transistor is configured to control access to the second memory cell.

Example 9 provides the memory device according to examples 7 or 8, where a gate stack of the second transistor is coupled to a first wordline, and a gate stack of the fourth transistor is coupled to a second wordline (i.e., the gates of the second and fourth transistors are individually controlled).

Example 10 provides the memory device according to example 9, where the gate stack of the second transistor is coupled to a first gate contact, the gate stack of the fourth transistor is coupled to a second gate contact, and each of the first gate contact and the second gate contact is provided over a different portion of the support structure.

Example 11 provides the memory device according to example 10, where each of the first gate contact and the second gate contact extends in a direction that is substantially perpendicular to the support structure.

Example 12 provides the memory device according to any one of examples 7-11, where a gate stack of the third transistor is electrically floating.

Example 13 provides the memory device according to any one of examples 7-12, where each of the second S/D region of the first transistor and the second S/D region of the third transistor is coupled to a via, where the via is coupled to a ground potential and extends in a direction that is substantially perpendicular to the support structure.

Example 14 provides the memory device according to example 13, where each of the first S/D region of the third transistor and the first S/D region of the fourth transistor is coupled to the ground potential, e.g., through the via according to example 13.

Example 15 provides the memory device according to any one of the preceding examples, where, for each nanoribbon of the first nanoribbon and the second nanoribbon, a width of the nanoribbon (i.e., a dimension measured in a plane parallel to the support structure and in a direction perpendicular to the long axis of the nanoribbon) is at least about 3 times larger than a height of the nanoribbon (i.e., a dimension measured in a plane perpendicular to the support structure), including all values and ranges therein, e.g., at least about 4 times larger, or at least about 5 times larger.

Example 16 provides the memory device according to any one of the preceding examples, where a gate stack of the first transistor includes a ferroelectric material.

Example 17 provides the memory device according to example 16, where the ferroelectric material includes one or more of a ferroelectric material including hafnium, zirconium, and oxygen; a ferroelectric material including hafnium, silicon, and oxygen; a ferroelectric material including hafnium, germanium, and oxygen; a ferroelectric material including hafnium, aluminum, and oxygen; or a ferroelectric material including hafnium, yttrium, and oxygen.

In some embodiments of example 16 or example 17, the ferroelectric material may have a thickness between about 1 nanometer and 10 nanometers (i.e., the ferroelectric material is a thin-film ferroelectric material).

Example 18 provides a memory device (or, more generally, an IC device) (e.g., the memory device 580-n, shown in FIG. 5) that includes a first semiconductor nanoribbon (e.g., the nanoribbon 304-n1, shown in FIG. 5); a second semiconductor nanoribbon (e.g., the nanoribbon 304-n2, shown in FIG. 5); a first transistor (e.g., the transistor 210-n1, shown in FIG. 5), having a first source or drain (S/D) region and a second S/D region in the first nanoribbon; and a second transistor (e.g., the transistor 210-n2, shown in FIG. 5), having a first S/D region and a second S/D region in the second semiconductor nanoribbon. In such a memory device, each of the first S/D region of the first transistor, the second S/D region of the first transistor, and the first S/D region of the second transistor is coupled to a ground potential, the second S/D region of the second transistor is coupled to a bitline, a gate stack of the first transistor is electrically floating, and a gate stack of the second transistor is coupled to a wordline.

Example 19 provides the memory device according to example 18, where the first nanoribbon extends in a direction substantially parallel to a support structure (e.g., a substrate, a chip, or a wafer) over which the memory device is provided, the second nanoribbon extends in a direction substantially parallel to the support structure and is stacked above the first nanoribbon so that the first nanoribbon is between the support structure and the second nanoribbon, and the bitline extends in a direction that is substantially perpendicular to the support structure.

Example 20 provides the memory device according to examples 18 or 19, where the memory device further includes features according to any one of examples 1-17.

Example 21 provides a method of fabricating a memory device (or, more generally, an IC device) (e.g., the memory device 480-n, shown in FIG. 4, or the memory device 580-n, shown in FIG. 5). The method includes providing a first nanoribbon (e.g., the nanoribbon 304-n1, shown in FIGS. 4-5) over a support structure (e.g., a substrate, a chip, or a wafer) so that the first nanoribbon extends in a direction substantially parallel to the support structure; providing a second nanoribbon (e.g., the nanoribbon 304-n1, shown in FIGS. 4-5) over the first nanoribbon so that the first nanoribbon is between the support structure and the second nanoribbon (i.e., the second nanoribbon extends in a direction substantially parallel to the support structure and is stacked above the first nanoribbon); providing a first transistor (e.g., the transistor 210-n1, shown in FIGS. 4-5), having a first source or drain (S/D) region and a second S/D region in the first nanoribbon; providing a second transistor (e.g., the transistor 210-n2, shown in FIGS. 4-5), having a first S/D region and a second S/D region in the second nanoribbon; electrically coupling the first S/D region of the first transistor and the first S/D region of the second transistor; electrically coupling the second S/D region of the first transistor to a ground potential; ensuring that a gate stack of the first transistor is electrically floating; and electrically coupling a gate stack of the second transistor to a wordline.

Example 22 provides the method according to example 21, further including providing the bitline that extends in a direction that is substantially perpendicular to the support structure and is coupled to one or more further transistors.

Example 23 provides the method according to examples 21 or 22, further including processes for fabricating a memory device according to any one of the preceding examples, e.g., the memory device according to any one of examples 1-17, or the memory device according to any one of examples 18-20.

Example 24 provides an IC package that includes an IC die, including one or more of the memory/IC devices according to any one of the preceding examples. The IC package may also include a further component, coupled to the IC die. In a further example, the further component is one of a package substrate, a flexible substrate, or an interposer. In a further example, the further component is coupled to the IC die via one or more first level interconnects. In a further example, the one or more first level interconnects include one or more solder bumps, solder posts, or bond wires.

Example 25 provides a computing device that includes a circuit board; and an IC die coupled to the circuit board, where the IC die includes one or more of the memory/IC devices according to any one of the preceding examples (e.g., memory/IC devices according to any one of examples 1-20), and/or the IC die is included in the IC package according to any one of the preceding examples (e.g., the IC package according to any one of the preceding examples).

Example 26 provides the computing device according to example 25, where the computing device is a wearable computing device (e.g., a smart watch) or handheld computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A memory device, comprising:
a support structure; and
a memory cell, comprising:
a first transistor, having a first source or drain (S/D) region and a second S/D region in a first nanoribbon, where the first nanoribbon extends in a direction substantially parallel to the support structure, and
a second transistor, having a first S/D region and a second S/D region in a second nanoribbon, where the second nanoribbon is stacked above the first nanoribbon so that the first nanoribbon is between the support structure and the second nanoribbon;
wherein:
the first transistor is configured to store a memory state of the memory cell, and
the second transistor is configured to control access to the memory cell.

2. The memory device according to claim 1, wherein the first S/D region of the first transistor is coupled to the first S/D region of the second transistor.

3. The memory device according to claim 1, wherein the second S/D region of the first transistor is coupled to a ground potential.

4. The memory device according to claim 3, wherein each of the first S/D region of the first transistor and the first S/D region of the second transistor is coupled to the ground potential.

5. The memory device according to claim 1, wherein a gate stack of the first transistor is electrically floating.

6. The memory device according to claim 1, wherein:
the second S/D region of the second transistor is coupled to a bitline, and
the bitline extends in a direction that is substantially perpendicular to the support structure.

7. The memory device according to claim 6, wherein:
the memory cell is a first memory cell,
the memory device further includes a second memory cell, the second memory cell comprising:
a third transistor, having a first S/D region and a second S/D region in a third nanoribbon, where the third nanoribbon is stacked above the second nanoribbon so that the second nanoribbon is between the first nanoribbon and the third nanoribbon, and
a fourth transistor, having a first S/D region and a second S/D region in a fourth nanoribbon, where the fourth nanoribbon is stacked above the third nanoribbon so that the third nanoribbon is between the second nanoribbon and the fourth nanoribbon, and the second S/D region of the fourth transistor is coupled to the bitline.

8. The memory device according to claim 7, wherein:
the third transistor is configured to store a memory state of the second memory cell, and
the fourth transistor is configured to control access to the second memory cell.

9. The memory device according to claim 7, wherein:
a gate stack of the second transistor is coupled to a first wordline, and
a gate stack of the fourth transistor is coupled to a second wordline.

10. The memory device according to claim 9, wherein:
the gate stack of the second transistor is coupled to a first gate contact,
the gate stack of the fourth transistor is coupled to a second gate contact, and
each of the first gate contact and the second gate contact is over a different portion of the support structure.

11. The memory device according to claim 10, wherein each of the first gate contact and the second gate contact extends in a direction that is substantially perpendicular to the support structure.

12. The memory device according to claim 7, wherein a gate stack of the third transistor is electrically floating.

13. The memory device according to claim 7, wherein each of the second S/D region of the first transistor and the second S/D region of the third transistor is coupled to a via, where the via is coupled to a ground potential and extends in a direction that is substantially perpendicular to the support structure.

14. The memory device according to claim 13, wherein each of the first S/D region of the third transistor and the first S/D region of the fourth transistor is coupled to the ground potential.

15. The memory device according to claim 1, wherein, for each nanoribbon of the first nanoribbon and the second nanoribbon, a width of the nanoribbon is at least 3 times larger than a height of the nanoribbon.

16. The memory device according to claim 1, wherein a gate stack of the first transistor includes a ferroelectric material.

17. A memory device, comprising:
a first nanoribbon;
a second nanoribbon;
a first transistor, having a first source or drain (S/D) region and a second S/D region in the first nanoribbon; and
a second transistor, having a first S/D region and a second S/D region in the second nanoribbon;
wherein:
each of the first S/D region of the first transistor, the second S/D region of the first transistor, and the first S/D region of the second transistor is coupled to a ground potential,
the second S/D region of the second transistor is coupled to a bitline,
a gate stack of the first transistor is electrically floating, and
a gate stack of the second transistor is coupled to a wordline.

18. The memory device according to claim 17, wherein:
the first nanoribbon extends in a direction substantially parallel to a support structure over which the memory device is provided,
the second nanoribbon is stacked above the first nanoribbon so that the first nanoribbon is between the support structure and the second nanoribbon, and
the bitline extends in a direction that is substantially perpendicular to the support structure.

19. A method of fabricating a memory device, the method comprising:
providing a first nanoribbon over a support structure so that the first nanoribbon extends in a direction substantially parallel to the support structure;
providing a second nanoribbon over the first nanoribbon so that the first nanoribbon is between the support structure and the second nanoribbon;
providing a first transistor, having a first source or drain (S/D) region and a second S/D region in the first nanoribbon;
providing a second transistor, having a first S/D region and a second S/D region in the second nanoribbon;
coupling the first S/D region of the first transistor and the first S/D region of the second transistor;
coupling the second S/D region of the first transistor to a ground potential;
ensuring that a gate stack of the first transistor is electrically floating; and
coupling a gate stack of the second transistor to a wordline.

20. The method according to claim 19, further comprising:
providing the bitline that extends in a direction that is substantially perpendicular to the support structure and is coupled to one or more further transistors.
